(19) United States
(12) Patent Application Publication
(10) Pub. No.: US 2002/0136061 A1
(43) Pub. Date: Sep. 26, 2002

(54) Method and memory system for writing in data

(76) Inventors: Robert Kaiser, Kaufering (DE); Florian Schamberger, Bad Reichenhall (DE); Helmut Schneider, Munchen (DE)

Correspondence Address: LERNER AND GREENBERG, P.A., Post Office Box 2480, Hollywood, FL, 33022-2480, US

(21) Appl. No.: 10/105,546

(22) Filed: Mar. 25, 2002

(30) Foreign Application Priority Data
Mar. 23, 2001 (DE) 101 14 443.1

(51) Int. Cl. G11C 5/00

(52) U.S. Cl. 365/189.01

(57) ABSTRACT

A method and a memory system temporarily store the addresses in a memory field during the writing-in of data. The addresses are applied to a write unit simultaneously with the data. Due to the intermediate storage of the addresses, the data can be input in a flexible manner, for example, even with a chronological delay in relation to the addresses.

### BACKGROUND OF THE INVENTION

### FIELD OF THE INVENTION

The invention relates to a method and a memory system for writing data into a memory cell of an addressable memory.

Methods for writing data into an addressable memory, and corresponding memory systems, are known which include, for example, double data rate SDRAM (Synchronous Dynamic Random Access Memory) systems. Here, data are transferred to a write unit with a specified data width and with a specified data clock pulse. In addition, the write unit contains the addresses of the memory cells in which the supplied data will be stored. In double data rate memories, the data are supplied to a first or to a second memory upon each rising and falling edge of a clock signal. In another specific embodiment, the data are read into the memory at only half frequency, i.e., with the rising or with the falling edge. When an address is present, the data are read into the corresponding memory cell of the memory. For the read-in process, the addresses and the data must be simultaneously present at the memory.

U.S. Pat. No. 5,781,500 discloses a memory system and a method for reading data into a memory system in which a start address is specified for a burst read-in process or a burst read-out process. Dependent on the start address, additional addresses are produced by incrementing the start address upward. Data are read in or out from the memory cells identified by the start address or the generated addresses.

If a new burst signal takes place, the generation of additional addresses dependent on the specified start address is interrupted, and a new start address is specified. Dependent on the new start address, by incrementing the start address, further addresses are again generated that identify memory cells from which data are read out or into which data are written.

### SUMMARY OF THE INVENTION

It is accordingly an object of the invention to provide a memory system and a method for writing data into an addressable memory in which data can be written to the memory only with the rising edge or with the falling edge. In addition, however, the memory system and the method allow data to be read with the rising and with the falling edge.

With the foregoing and other objects in view there is provided, in accordance with the invention, a method for writing data into an addressable memory having memory cells, that includes: supplying an address before supplying data; temporarily storing the address; forwarding the address to an address decoder in a time-delayed fashion such that the address is supplied to the address decoder and the data is supplied to an amplifier circuit almost simultaneously; and writing the data into a memory cell being selected by the address decoder.

In accordance with an added mode of the invention, the method includes steps of: at a first time pulse, writing first data into an input/output circuit; at a second time pulse, subsequent to the first time pulse, writing second data into an input/output circuit; temporarily storing the first data and the second data; and at a third time pulse, simultaneously forwarding the first data and the second data to the amplifier circuit in parallel.

In accordance with an additional mode of the invention, the method includes steps of: writing the first data and the second data into the input/output circuit synchronously with a rising edge and a falling edge of an external clock signal; and supplying the first data and the second data to the amplifier circuit using an internal clock pulse.

In accordance with another mode of the invention, the method includes steps of: upon receiving a first clock signal, storing the address in a first intermediate memory synchronously with an internal clock signal; upon receiving a second clock signal, writing the address from the first intermediate memory into a second intermediate memory synchronously with the internal clock signal; and subsequently, upon receiving a third clock signal, supplying the address from the second intermediate memory to the address decoder synchronously with the internal clock signal.

In accordance with a further mode of the invention, the method includes steps of: triggering an internal loading command synchronously with an internal clock signal; supplying the data from an input/output circuit to the amplifier circuit synchronously with the internal loading command; and supplying the address to the address decoder synchronously with the internal loading command.

In accordance with a further added mode of the invention, the method includes steps of: supplying a start address to an address counter; with the address counter, incrementing the start address by a predetermined non-zero number of addresses; outputting a new address in a chronologically synchronous manner with new data being supplied; and for each address in an input/output circuit, writing temporarily stored data into a memory cell being addressed by the address in the input/output circuit.

With the foregoing and other objects in view there is also provided, in accordance with the invention, a memory system, that includes: a memory having memory cells; lines; an address decoder connected to the memory cells via the lines; an input/output circuit connected to the memory cells; an address input; and an intermediate memory system connecting the address input to the address decoder. The output/input circuit supplies data for storage in addressed ones of the memory cells. The address decoder has a clock input for receiving an internal clock signal. The input/output circuit has a clock input for receiving the internal clock signal. The intermediate memory system is for storing an address. The intermediate memory system is clocked by the internal clock signal to transfer the address stored therein to the address decoder. The address is temporarily stored such that the address is supplied to the memory simultaneously with the data.

In accordance with an added feature of the invention, the intermediate memory system includes a first intermediate memory and a second intermediate memory; the first intermediate memory has an input connected to the address input; the second intermediate memory has an input and an output; the first intermediate memory has an output connected to the input of the second intermediate memory; the output of the second intermediate memory is connected to the address decoder; the first intermediate memory has a clock input for receiving a first clock signal that is dependent on the internal clock signal; each time the first clock signal is supplied, the first intermediate memory acquires data input at the input thereof and supplies the data input at the input thereof to the output of the first intermediate memory until a next first clock signal; the second intermediate memory has a second clock input for receiving a second clock signal that is dependent upon the internal clock signal; the second intermediate memory has a third clock input for receiving a third clock signal that is dependent upon the internal clock signal; the third clock signal is chronologically offset from the second clock signal; upon receipt of the second clock signal, the second intermediate memory stores data input at the input thereof until a next second clock signal is received; and upon receiving the second clock signal, the output of the second intermediate memory supplies the data stored therein to the address decoder.

In accordance with an additional feature of the invention, there is provided, a control unit for producing the first clock signal, the second clock signal, and the third clock signal synchronously with the internal clock signal.

In accordance with another feature of the invention, there is provided, a connection line routed between the address decoder and the second intermediate memory; and an adder having an output connected to the connection line. The adder has an input, a control input, and a fourth clock input. The input of the adder acquires an address that is being input on the connection line. The adder increments the address acquired at the input thereof by a predetermined value and thereby obtains an incremented address. Upon receiving a fourth clock signal at the fourth clock input, the output of the adder outputs the incremented address to the connection line.

In accordance with a further feature of the invention, there is provided, a clock pulse generator running synchronously with the internal clock signal. The clock pulse generator is connected to the fourth clock input of the adder.

Preferably, the addresses are temporarily stored or buffered and are forwarded to the memory in time-delayed fashion, simultaneously with the datum. In this way, the address and the datum are output synchronously to the memory so that the data are written to the addressed memory cells without a time delay. For this purpose, an intermediate memory system is provided that is connected upstream from the memory and that delays the address, which is clocked by an internal clock signal, by at least one clock pulse. The intermediate memory system forwards the address to the memory simultaneously with the data.

Preferably, the addresses are stored in a first intermediate memory synchronously with the internal clock signal, are transferred to a second intermediate memory upon a following clock signal, and are supplied to the memory from the second intermediate memory upon a third clock signal. Due to the two temporary memories that are provided, a chronological decoupling is possible between the specification of a new address and the handing over of a previous address to the memory. In this way, a more flexible handling of the address is possible.

Preferably, it is indicated via an internal loading command that the input datum will be stored in the memory cell of the input address. In this way, the specification of the data using an external clock signal can be decoupled from the processing of the data using an internal clock signal. The use of an external and an internal clock signal enables a more flexible handling of the data, whereby the data are preferably processed internally with a greater data width than is supplied externally.

Preferably, in a read-in process, not all addresses are supplied from outside. Rather, only one start address is supplied to a counter, and the subsequent addresses are generated by the counter itself. In this way, more time is available to supply the address from the outside.

Preferably, the data are written to an intermediate memory with a rising and with a falling edge of an external clock signal, according to the double data rate principle. Subsequently, the data are supplied to the memory using an internal clock signal, whereby the internal clock signal uses only a rising or a falling edge. In this way, the clock pulse between the supplying of the data and the write process is reduced. In this way, it is possible for data to be supplied using the double data rate principle, and to be stored in the memory using the single data rate principle.

Preferably, the first clock signal is produced synchronously with an external control signal. The second clock signal is preferably generated one clock period after the external control signal from an edge of the internal clock signal. In addition, the internal load signal is preferably generated two clock periods after the external control signal, synchronously with the internal clock signal, whereby the internal load signal causes an immediate writing in of the data.

Other features which are considered as characteristic for the invention are set forth in the appended claims.

Although the invention is illustrated and described herein as embodied in a method and memory system for writing in data, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 schematically shows a synchronous dynamic memory with random access;

FIG. 2 shows an address counter;

FIG. 3 is a time diagram showing clock signals during a write process to the dynamic memory; and

FIG. 4 is a time diagram showing an incrementing process of an adder.

### DESCRIPTION OF THE PREFERRED EMBODIMENTS

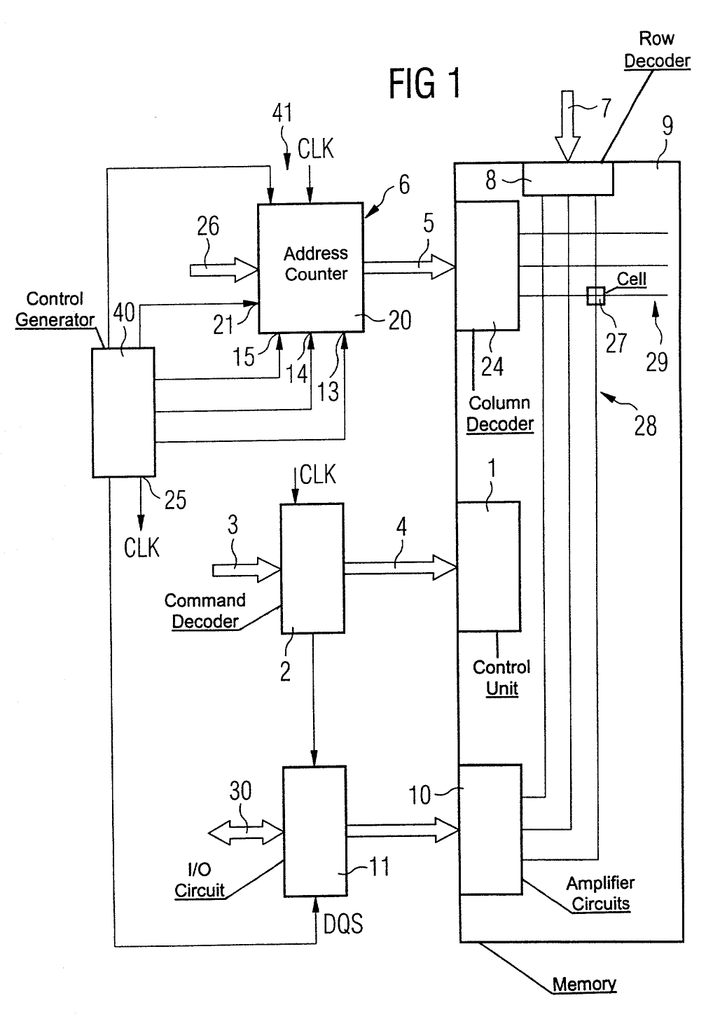

Referring now to the figures of the drawing in detail and first, particularly, to FIG. 1 thereof, there is shown a command decoder 2 that receives control signals via inputs 3. The command decoder 2 is connected to a control unit 1 of a memory 9 via an output 4. The command decoder 2 determines control commands from the supplied control signals, and gives the control commands to the control unit 1. In addition, an address counter 6 is provided that is connected to a column decoder 24 via an address output 5. The address counter 6 has an address input 26 that receives the addresses of the column lines of the memory cells of the memory 9 to which data will be written. The address counter 6 forwards the addresses to the column decoder 24. The column decoder 24 activates the addressed column lines 29 of the memory 9. In addition, the memory 9 has a row decoder 8 with a second address input 7 receiving the addresses of the row lines of the memory cells to which data will be written. The memory 9 has row lines 28 and column lines 29. The column lines 29 are connected to amplifier circuits 10. The row decoder 8 can be connected to row lines 28, and the column decoder 24 can be connected to column lines 29. The row lines 28 and the column lines 29 are situated perpendicularly with respect to one another. A respective memory cell 27 is located at each of the crossing points between a row line 28 and a column line 29. The memory cell 27 can be connected to a row line 28 and to a column line 29.

The amplifier circuit 10 is connected to an output/input circuit 11 having first outputs/inputs 30.

The address counter 6 has a first clock input 13, a second clock input 14, a third clock input 15, and a fourth clock input 21. A first clock signal Clk1 is supplied via the first clock input 13, a second clock signal Clk2 is supplied via the second clock input 14, a third clock signal Clk3 is supplied via the third clock input 15, and a fourth clock signal Clkinc is supplied via the fourth clock input 21.

In addition, a control generator 40 generates the first, second, third, and fourth clock signals, and generates an external clock signal DQS. The external clock signal DQS is supplied to the output/input circuit 11. In addition, the control generator 40 generates a burst signal that is supplied to the address counter via a burst input 41.

In the following, the addressing of the memory cells is explained in more detail: The addresses are transferred, as column addresses and row addresses, to the address counter 6 via the address input 26, or to the row decoder 8 via the second address inputs 7. The row decoder 8 determines, from the row addresses, the row lines 28 that will be accessed, and accesses the corresponding row lines 28.

The addresses of the column lines 29 of memory cells 27 to which data will be written are supplied to the address counter 6. The address counter 6 is fashioned as a latch memory. The control generator 40 supplies a first clock signal to the address counter 6. When the first clock signal is input, the address counter 6 stores the addresses that are input to the address input 26. The address counter 6 outputs these addresses at the address output 5 after receiving a second clock signal.

The address counter 6 preferably has an adding function that consists of the following: upon receipt of a third clock signal, the address counter 6 increases a start address that is supplied via the address input 26, by the value 1, and outputs it at the address output 5. This process is repeated for each third clock signal that is supplied such that the last-indicated address is always increased.

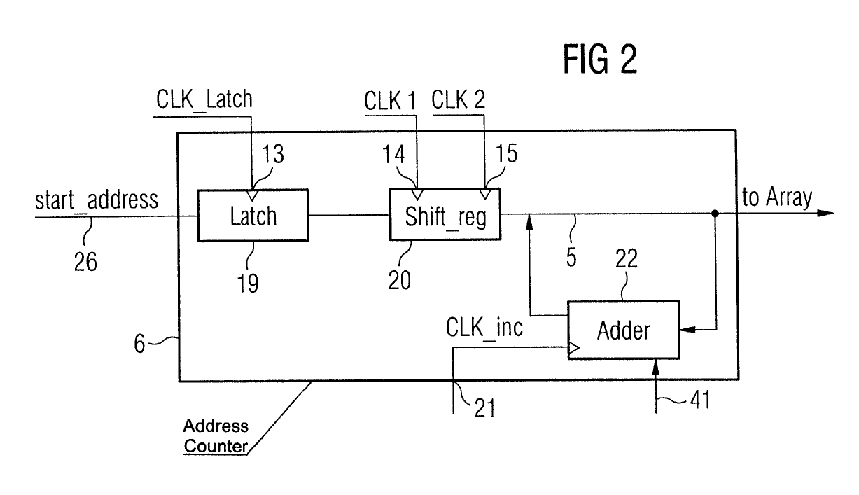

FIG. 2 shows a simple specific embodiment of the address counter 6 having a first intermediate memory 19 with a clock input, a second intermediate memory 20 with two clock inputs, and an adder 22. The first intermediate memory 19 stores the address that is input to its input upon receipt of a clock signal, and outputs the stored address at its output until the next clock signal. The output of first intermediate memory 19 is connected to the input of the second intermediate memory 20.

Upon receipt of the second clock signal, the second intermediate memory 20 stores the addresses that are input to its input. The second intermediate memory 20 outputs the stored addresses to the column decoder 24 using the address output 5 upon receipt of the third clock signal. In addition to the column decoder 24, the adder 22 also acquires the address that is output by the address output 5. In addition, the adder 22 increments the acquired address upward by a predetermined value, and upon receipt of a fourth clock signal Clkinc, the adder 22 outputs the incremented address to the address output 5. After the emission of the incremented address, the adder 22 acquires the incremented address that is present at the address output 5, and upon receipt of a fourth clock signal, again increments the acquired address upward by a predetermined value. Subsequently, the adder 22 outputs the address, which has been incremented upward twice, to the address output 5. The adder 22 executes this method for a predetermined number of increments. For the initiation and termination of this incrementing process, the adder 22 has a burst input 41, via which a corresponding start or stop signal for a burst read-in or a burst read-out process is supplied from the control generator 40.

Simultaneously, the control generator 40 ensures that during the time in which the adder 22 increments the addresses, a third clock signal is not output to the second intermediate memory 20. The second intermediate memory 20 therefore does not output a new start address to the address output 5 during the incrementing process of the adder 22.

After the termination of an incrementing process, the adder 22 waits for the second intermediate memory 20 to specify a new start address, and waits for a start signal via the burst input 41.

The control generator 40 preferably outputs the fourth clock signals at equidistant time intervals. Based on the specified method, for a write process in which a plurality of successive addresses of column lines are addressed, it is possible to address the column lines without having to supply addresses continuously via the address input 26. Thus, only the start address is supplied via the address input 26, and the incrementing of the addresses is carried out by the adder 22.

The column decoder 24 decodes the addresses of the physical column lines 29 from the supplied addresses, and given the application of a physical address, writes the data that are input to the amplifier circuits 10 into the memory 9 via the addressed physical column lines. The data are thereby written into the memory cells 27 that are connected to the column lines via the addressed column lines 29.

On the basis of the specified method, it is possible for new start addresses to be already supplied via the address register 6, when data are still simultaneously being written into the memory 9 in accordance with a previous start address. In addition, using a second intermediate memory 20 offers a flexible temporary storage of a start address.

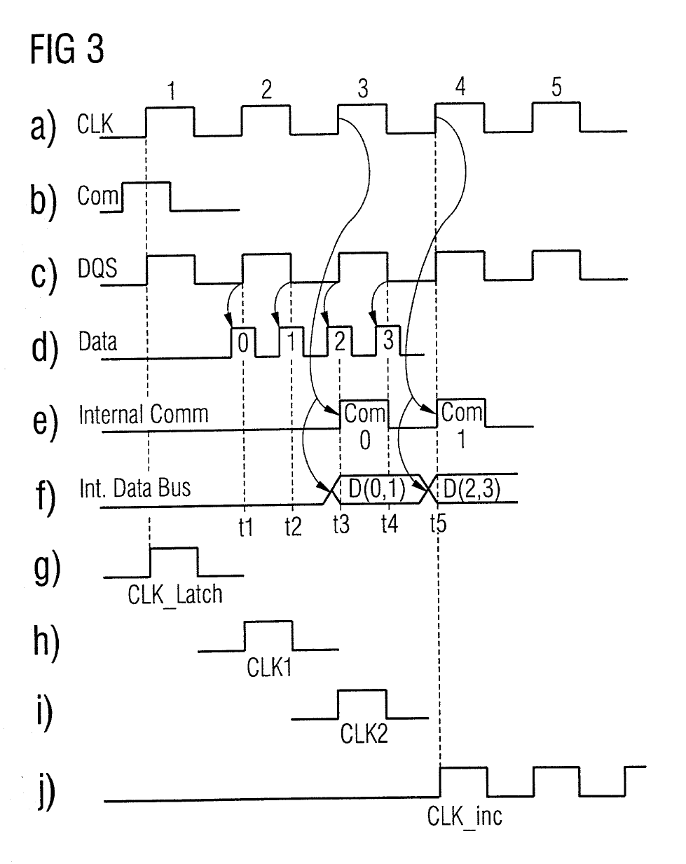

A method for writing in data is explained in more detail on the basis of the signal curves shown in FIG. 3. In a first diagram line a), an internal clock signal CLK is shown that is generated by the control generator 40 and output via a clock output 25. In a second diagram line b), an external control signal (schematically shown) is supplied to the command decoder 2. In the technical realization, the control signal results from a combination of control signals CS, WE, CAS, and RAS. If the control command that is present at the command decoder 2 has a high-level, and if in addition, a rising edge of the clock signal CLK is taking place, a write command is forwarded to the control unit 1. The control unit 1 then designates a write process in which a multiplicity of data are written into memory 9 in the form of a serial stream of data.

In a third diagram line c), an external clock signal DQS is shown that is used for the clocked reading-in of data. The external clock signal is generated by the control generator 40 and is supplied to the output/input circuit 11.

A fourth diagram line d) shows a data signal that indicates, with a high state, that data are written into the memory. The writing of the data is respectively triggered by a rising or by a falling edge of the external clock signal DQS. For example, at time t1, a predetermined number of data (the zeroth data item) are supplied to the output/input circuit 11. At the following falling edge of the external clock signal DQS (at time t2), a predetermined number of first data are supplied to the output/input circuit 11. At the following time t3 (at the second rising edge), the first control unit 1 generates an internal loading command COMO, shown in diagram line e), after recognizing the write command. The internal loading command COMO is supplied to the output/input circuit 11. After receipt of the internal loading command COMO, the output/input circuit 11 forwards the temporarily stored data to the amplifier circuit 10.

In a seventh diagram line g), the chronological position of the first clock signal CLK_Latch is shown, which is output by the control generator 40 to the first intermediate memory 19. Given a high level of the first clock signal, the first intermediate memory 19 stores the address that is input to its input, and outputs the address in a somewhat time-delayed fashion at the output, until the first clock signal again has a high level.

In the eighth diagram line h), a second clock signal is shown. With the rising edge of the second signal of the internal clock signal CLK, the control generator 40 gives a second clock signal CLK1 to the second intermediate memory 20. Given a high level of the second clock signal, the second intermediate memory 20 acquires the address that is input to its input, and stores the acquired address until receiving a new second clock signal.

In a ninth diagram line i), a third clock signal CLK2 is shown. At the rising edge of the clock signal CLK, the control generator 40 generates a third clock signal CLK2 that is likewise supplied to the second intermediate memory 20. Given a high level of the third clock signal, the second intermediate memory 20 outputs the address stored in the second intermediate memory 20 to the address output 5.

On the basis of the diagram, it can be seen that the second intermediate memory 20 outputs the address to the address output 5 simultaneously with the internal loading command Com0 (FIG. 2e). Thus, the data and the addresses are output to memory 9 simultaneously. Consequently, the addresses and the data are supplied in a coordinated manner. The data are written into the column lines 29, which are determined by the addresses, via the amplifier circuits 10.

In the tenth diagram line j), the fourth clock signal CLK_inc of the adder 22 is shown. The adder 22 is clocked by the control generator 40 in a manner corresponding to the internal clock signal CLK, and is supplied with the fourth clock signal Clkinc, so that the adder outputs a new address that has been incremented to the column decoder 24, synchronously with the internal clock signal. The adder 22 executes this process until the adder 22 receives an end signal from the second control unit 23. Likewise, at the beginning of an incrementing process, the adder 22 receives a start signal from the control generator 40 via the burst input 41.

At time t3, the rising edge of the DQS signal controls a reading-in process of a second group of data into the amplifier circuit 10. At time t4, at the following falling edge of external clock signal DQS, a third group of data is written into the amplifier circuit 10. The rising edge of the fourth internal clock signal in turn produces an internal write command Com1, and the data is forwarded to the amplifier circuit 10. Preferably, with the rising and falling edge of the internal clock signal, the data are routed to the output/input circuit 11, and are forwarded from the output/input circuit 11 to the amplifier circuit 10 only with the rising or with the falling edge, but with a doubled data width.

Simultaneously, at time t5, the address is applied to the column decoder 24 via the first incremented address that is outputted by the adder 22. Thus, the address and the data to be written in are input simultaneously, so that the data can be written into memory 9. The amplifier circuit 10 and the column decoder 24 represent a write unit that reads the input data into the addressed column lines 29 upon receipt of a new address.

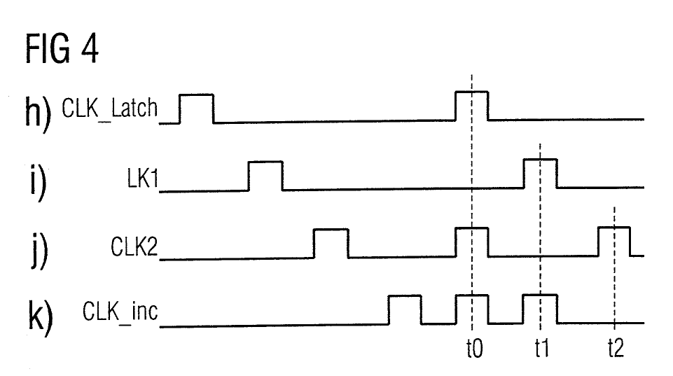

FIG. 4 schematically shows the situation in which the adder 22 is still outputting new addresses to the address output 5 (line k), while the first intermediate memory 19 already stores a new start address (line h). This takes place at time t0. At time t1, the new start address is transferred to the second intermediate memory 20 (line i). At time t2, the new address is output by second intermediate memory 20 to the address output 5. In this specific embodiment, it is determined that the adder 22 increments the start address only for three new addresses, and subsequently waits for a new start address to be supplied.

On the basis of the specified system, it is possible to supply the data to output/input circuit 11 at the doubled data rate, with the rising and falling edge of the external clock signal, and to process the addresses and the data internally according to the single data rate principle, at half frequency.

We claim:

1. A method for writing data into an addressable memory having memory cells, which comprises:
supplying an address before supplying data;
temporarily storing the address;
forwarding the address to an address decoder in a time-delayed fashion such that the address is supplied to the address decoder and the data is supplied to an amplifier circuit almost simultaneously; and
writing the data into a memory cell being selected by the address decoder.

2. The method according to claim 1, which comprises:
at a first time pulse, reading first data into an input/output circuit;
at a second time pulse, subsequent to the first time pulse, reading second data into an input/output circuit;
temporarily storing the first data and the second data; and
at a third time pulse, simultaneously forwarding the first data and the second data to the amplifier circuit in parallel.

3. The method according to claim 2, which comprises:
reading the first data and the second data into the input/output circuit synchronously with a rising edge and a falling edge of an external clock signal; and
supplying the first data and the second data to the amplifier circuit using an internal clock pulse.

4. The method according to claim 1, which comprises:
reading the data into an input/output circuit synchronously with a rising edge and a falling edge of an external clock signal; and
supplying the data to the amplifier circuit using an internal clock pulse.

5. The method according to claim 1, which comprises:
upon receiving a first clock signal, storing the address in a first intermediate memory synchronously with an internal clock signal;
upon receiving a second clock signal, reading the address from the first intermediate memory into a second intermediate memory synchronously with the internal clock signal; and subsequently
upon receiving a third clock signal, supplying the address from the second intermediate memory to the address decoder synchronously with the internal clock signal.

6. The method according to claim 1, which comprises:
triggering an internal loading command synchronously with an internal clock signal;
supplying the data from an input/output circuit to the amplifier circuit synchronously with the internal loading command; and
supplying the address to the address decoder synchronously with the internal loading command.

7. The method according to claim 1, which comprises:
supplying a start address to an address counter;
with the address counter, incrementing the start address by a predetermined non-zero number of addresses;
outputting a new address in a chronologically synchronous manner with new data being supplied; and
for each address in an input/output circuit, writing temporarily stored data into a memory cell being addressed by the address in the input/output circuit.

8. A memory system, comprising:
a memory having memory cells; lines;
an address decoder connected to said memory cells via said lines;
an input/output circuit connected to said memory cells;
an address input; and
an intermediate memory system connecting said address input to said address decoder;
said output/input circuit for supplying data for storage in addressed ones of said memory cells;
said address decoder having a clock input for receiving an internal clock signal;
said input/output circuit having a clock input for receiving the internal clock signal;
said intermediate memory system for storing an address;
said intermediate memory system being clocked by the internal clock signal to transfer the address stored therein to said address decoder; and
the address being temporarily stored such that the address is supplied to said memory simultaneously with the data.

9. The memory system according to claim 8, wherein:
said intermediate memory system includes a first intermediate memory and a second intermediate memory;
said first intermediate memory has an input connected to said address input;
said second intermediate memory has an input and an output;
said first intermediate memory has an output connected to said input of said second intermediate memory;
said output of said second intermediate memory is connected to said address decoder;
said first intermediate memory has a clock input for receiving a first clock signal that is dependent on the internal clock signal;
each time the first clock signal is supplied, said first intermediate memory acquires data input at said input thereof and supplies the data input at said input thereof to said output of said first intermediate memory until a next first clock signal;
said second intermediate memory has a second clock input for receiving a second clock signal that is dependent upon the internal clock signal;
said second intermediate memory has a third clock input for receiving a third clock signal that is dependent upon the internal clock signal;
the third clock signal is chronologically offset from the second clock signal;
upon receipt of the second clock signal, said second intermediate memory stores data input at said input thereof until a next second clock signal is received; and
upon receiving the second clock signal, said output of said second intermediate memory supplies the data stored therein to said address decoder.

10. The memory system according to claim 9, comprising: a control unit for producing the first clock signal, the second clock signal, and the third clock signal synchronously with the internal clock signal.

11. The memory system according to claim 9, comprising:
a connection line routed between said address decoder and said second intermediate memory; and
an adder having an output connected to said connection line;
said adder having an input, a control input, and a fourth clock input;
said input of said adder acquiring an address being input on said connection line;
said adder incrementing the address acquired at said input thereof by a predetermined value and thereby obtaining an incremented address; and
upon receiving a fourth clock signal at said fourth clock input, said output of said adder outputting the incremented address to said connection line.

12. The memory system according to claim 8, comprising:
a connection line routed between said address decoder and said second intermediate memory; and
an adder having an output connected to said connection line;
said adder having an input, a control input, and a fourth clock input;
said input of said adder acquiring an address being input on said connection line;
said adder incrementing the address acquired at said input thereof by a predetermined value and thereby obtaining an incremented address; and
upon receiving a fourth clock signal at said fourth clock input, said output of said adder outputting the incremented address to said connection line.

13. The memory system according to claim 12, comprising:
a clock pulse generator running synchronously with the internal clock signal;
said clock pulse generator being connected to said fourth clock input of said adder.
